(19) United States
(12) Patent Application Publication
(10) Pub. No.: US 2018/0191131 A1
(43) Pub. Date: Jul. 5, 2018

(54) HEAT-DISSIPATING SEMICONDUCTOR ASSEMBLY

(71) Applicant: LuxNet Corporation, Zhongli City (TW)

(72) Inventors: Hsing-Yen Lin, Zhongli City (TW); Pi-Cheng Law, Zhongli City (TW); Po-Chao Huang, Zhongli City (TW); Bo-Wei Liu, Zhongli City (TW); Ya-Hsin Deng, Zhongli City (TW); Hua-Hsin Su, Zhongli City (TW)

(21) Appl. No.: 15/670,624

(22) Filed: Aug. 7, 2017

(30) Foreign Application Priority Data
Dec. 30, 2016 (TW) 105220104

(51) Int. Cl. H01S 5/024; H01S 5/022

(52) U.S. Cl. CPC H01S 5/02469; H01S 5/4031; H01S 5/02236

(57) ABSTRACT

The invention provides a heat-dissipating semiconductor assembly, comprising: a heat-dissipating substrate, a metal solder layer, and an edge emitting laser diode. The heat-dissipating substrate has one side formed with a flat surface for mounting the edge emitting laser diode. The edge emitting laser diode is mounted on the metal solder layer, and by lowering the active area of the edge emitting laser diode, the active area of the edge emitting laser diode is drawn close to one side of the heat-dissipating substrate. The edge emitting laser diode has an optical output direction parallel to the flat surface of the heat-dissipating substrate, and the heat-dissipating substrate and/or the metal solder layer have a groove. The ridge of the edge emitting laser diode is aligned with an opening formed in the groove of the heat-dissipating substrate, thereby preventing the heat-dissipating substrate and metal solder layer from contacting the ridge of the edge emitting laser diode.

### BACKGROUND OF THE INVENTION

### 1. Technical Field

The present invention relates a heat-dissipating semiconductor assembly, more particularly to a heat-dissipating substrate with the groove form for high power semiconductor assembly.

### 2. Description of Related Art

As optical communication devices become more performative, they have been developed to be more compact, more capable, and maturer in terms of power, data transfer rate, thermal stability as well as voltage endurance. Laser diodes represent one of the most extensively used segments. When operating, a laser diode unavoidably generates a great quantity of heat. If the heat is not released timely, the junction of the laser diode can become hot and this can jeopardize the device's performance and service life, in turn blighting the device's reliability. Hence, for ensuring reliability, it is necessary to improve the device's heat dissipation.

In the field of optical communication, heat dissipation for laser diodes have long been an issue of top priority for the academic and industrial researchers to work on. A traditional laser diode is metallically wired and packaged with a heat-dissipating substrate. Metal has good thermal conductivity, so thermal conduction to the heat-dissipating substrate can be achieved through the metal wire. However, the contacting area between the metal wire and the electrodes of the laser diode is too small and the distance from the light-emitting area of the laser diode to the heat-dissipating substrate is too far to provide timely heat dissipation, thus not able to ensure the device's performance and service life. Therefore, the inventor of the present invention has paid effort to devise a heat-dissipating semiconductor assembly that effectively addresses the problem related to inferior heat dissipation of laser diodes.

### SUMMARY OF THE INVENTION

The objective of the present invention is to solve the problem related to inferior heat dissipation, and in turn low optical output power and short service life of laser diodes as seen in the prior art.

To solve above problems, the present invention provides a heat-dissipating semiconductor assembly, comprising: a heat-dissipating substrate and an edge emitting laser diode mounted on the heat-dissipating substrate. The heat-dissipating substrate has one side formed with a flat surface. The edge emitting laser diode includes an active area and a rigid deposited on one side of a light-emitting area of the active area. The edge emitting laser diode is mounted on the heat-dissipating substrate, and by lowering the active area of the edge emitting laser diode, the active area of the edge emitting laser diode is drawn closer to one side of the heat-dissipating substrate, in which the edge emitting laser diode has an optical output direction parallel to the flat surface of the heat-substrate, and the heat-dissipating substrate has a groove so that the ridge of the edge emitting laser diode is aligned with an opening of the groove of the heat-dissipating substrate, thereby preventing the heat-dissipating substrate from contacting the ridge of the edge emitting laser diode.

Further, the heat-dissipating semiconductor assembly further comprises a metal solder layer deposited on the heat-dissipating substrate and located at two sides of the groove for holding the edge emitting laser diode in position.

Further, the distance from the active area to the contacting surface between the edge emitting laser diode and the metal solder is 2 μm to 14 μm.

Further, the metal solder layer is made of a material containing gold-tin alloy.

Further, the heat-dissipating substrate is a ceramic board.

Further, the heat-dissipating substrate is made of a material containing aluminum nitride (AlN), silicon carbide (SiC), or aluminum oxide (Al₂O₃).

Further, the width of the groove is wider than the width of the ridge of the edge emitting laser diode.

Further, the groove extends across the flat surface of the heat-dissipating substrate from one side to the opposite side.

Another object of the present invention is to provide a heat-dissipating semiconductor assembly, comprising: a heat-dissipating substrate, a metal solder layer deposited on the heat-dissipating substrate, and an edge emitting laser diode deposited on the metal solder layer. The heat-dissipating substrate has one side formed with a flat surface. The metal solder layer is deposited on the flat surface of the heat-dissipating substrate and having a groove. The edge emitting laser diode includes an active area and a rigid deposited on one side of a light-emitting area of the active area. The edge emitting laser diode is mounted on the metal solder layer, and by lowering the active area of the edge emitting laser diode, the active area of the edge emitting laser diode is drawn closer to one side of the heat-dissipating substrate. The edge emitting laser diode has an optical output direction parallel to the flat surface of the heat-dissipating substrate, and the rigid of the edge emitting laser diode is aligned with an opening formed in the groove of the metal solder layer, thereby preventing the metal solder layer from contacting the rigid of the edge emitting laser diode.

Further, the distance from the active area to the contact surface between the edge emitting laser diode and the metal solder layer is 2 μm to 14 μm.

Further, the metal solder layer is made of a material containing gold-tin alloy.

Further, the heat-dissipating substrate is a ceramic board.

Further, the heat-dissipating substrate is made of a material containing aluminum nitride (AlN), silicon carbide (SiC), or aluminum oxide (Al₂O₃).

Further, the width of the groove is wider than the width of the rigid of the edge emitting laser diode.

Therefore, comparing to the prior art, the present invention has advantages described as below:

1. The disclosed heat-dissipating semiconductor assembly has the edge emitting laser diode deposited on the metal solder layer and has the active area of the edge emitting laser diode close to the heat-dissipating substrate by lowering the active area of the edge emitting laser diode, thereby shortening the heat conducting path of the edge emitting laser diode, and effectively conducting the heat generated by the edge emitting laser diode to the heat-dissipating substrate in the shortened heat conducting path.

2. The disclosed heat-dissipating semiconductor assembly has the groove formed on the heat-dissipating substrate, and has the ridge of the edge emitting laser diode aligned with the opening of the groove, thereby preventing the heat-dissipating substrate from damaging the ridge of the edge emitting laser diode and in turn ruining its light-emitting quality.

### BRIEF DESCRIPTION OF THE DRAWINGS

FIG. 1 shows a perspective schematic view of the first embodiment of the present invention.

FIG. 2 shows a cross-sectional schematic view of the first embodiment of the present invention.

FIG. 3 shows a perspective schematic view of the second embodiment of the present invention.

FIG. 4 shows a sectional schematic view of the second embodiment of the present invention.

### DETAILED DESCRIPTION OF THE EMBODIMENT OF THE INVENTION

Descriptions and techniques of the present invention would be illustrated in detail with reference to the accompanying drawings herein. Furthermore, for easier illustrating, the drawings of the present invention are not a certainly the practical proportion and are not limited to the scope of the present invention.

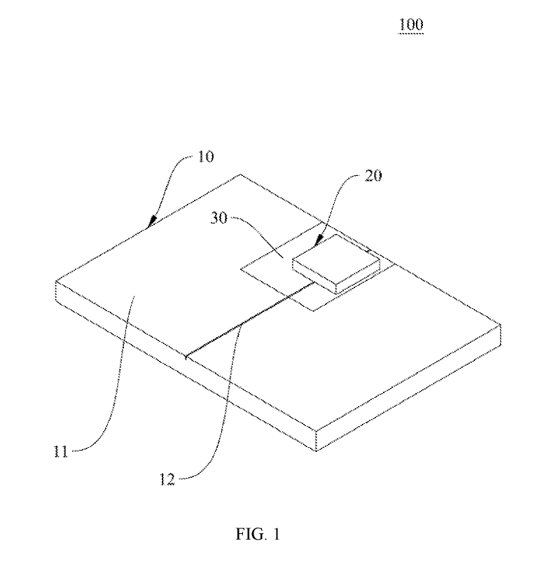

Please first refer to FIG. 1 for a perspective schematic view of the first embodiment of the present invention.

The present embodiment provides a heat-dissipating semiconductor assembly. The heat-dissipating semiconductor assembly 100 primarily comprises a heat-dissipating substrate 10 and an edge emitting laser diode 20. The heat-dissipating substrate 10 has its one side formed with a flat surface 11, a metal solder layer 30, and a groove 12 formed on the flat surface 11. The heat-dissipating substrate 10 can be a ceramic board that features high thermal conductivity, low thermal resistance, long service life, and good thermal endurance. With high thermal conductivity and good thermal endurance, the ceramic board can effectively transfer heat for heat dissipation. Particularly, the heat-dissipating substrate 10 can be made of a ceramic material containing aluminum nitride (AlN), silicon carbide (SiC), or aluminum oxide (Al₂O₃) or a composite material composed of the foregoing materials, and the present invention places no limitation thereon. In one preferred embodiment, the heat-dissipating substrate is preferably made of a material based on aluminum nitride (AlN). With high thermal conductivity and low coefficient of thermal expansion (CTE), aluminum nitride is effective in preventing offset beam of the edge emitting laser diode 20 that would otherwise be caused by thermal expansion or contract of the heat-dissipating substrate 10 made of other materials under thermal variation.

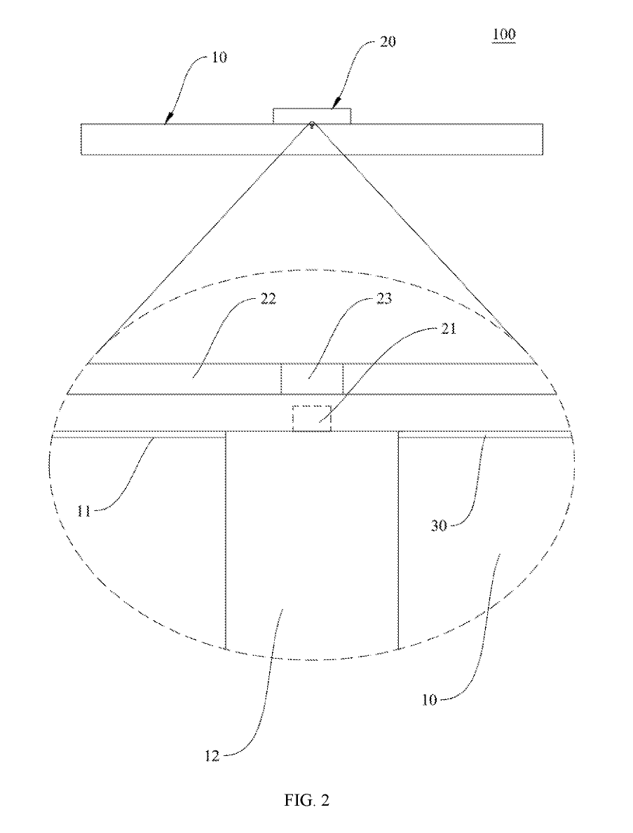

Please refer to FIG. 2 for a cross-sectional schematic view of the first embodiment of the present invention.

The edge emitting laser diode 20 comprises an active area 22 and a ridge 21 deposited on one side of a light-emitting area 23 of the active area 22. Particularly, the ridge 21 can be a P-type semiconductor, and the active area 22 is an area of the P-N junction. An electrode layer (not shown in drawing) is optionally formed on the bottom side of the ridge 21 to cover the outside of the ridge 21. The electrode layer can extend in both sides to the upper side of the metal solder layer 30. The edge emitting laser diode 20 is mounted on the heat-dissipating substrate 10. By lowering the active area 22 of the edge emitting laser diode 20, the active area 22 of the edge emitting laser diode 20 is drawn closer to one side of the heat-dissipating substrate 10. The edge emitting laser diode 20 has its optical output direction parallel to the flat surface 11 of the heat-dissipating substrate 10. The heat-dissipating substrate 10 is also provided with a groove 12. The ridge 21 of the edge emitting laser diode 20 is aligned with an opening of the groove 12 on the heat-dissipating substrate 10. The metal solder layer 30 is formed at two sides of the groove 12 for holding the edge emitting laser diode 20 in position, thereby preventing the heat-dissipating substrate 10 and the metal solder layer 30 from contacting the ridge 21 of the edge emitting laser diode 20. While the ridge 21 in the drawing is depicted as a block, the ridge 21 can be one jutting out of, recessed from, or flush with the bottom side of the laser semiconductor, according to the type of the laser semiconductor. The present invention places no limitation on the way the ridge 21 is realized. Particularly, the edge emitting laser diode 20 can be a ridge-type laser diode, a planar buried laser diode, a stripe buried laser diode, or other laser diodes having a ridge structure. The present invention places no limitation thereon.

The groove 12 on the heat-dissipating substrate 10 is wider than the ridge 21 of the edge emitting laser diode 20. Particularly, the minimum width of the groove 12 of the heat-dissipating substrate 10 is about 1˜2 μm greater than the width of the ridge 21 of the edge emitting laser diode 20, wherein a proper margin has to be maintained lest the ridge 21 should be damaged. In one preferred embodiment, the groove 12 extends across the flat surface 11 of the heat-dissipating substrate 10 from one side to the opposite side, thereby facilitating visual alignment of the ridge 21 of the edge emitting laser diode 20 during installation of the edge emitting laser diode 20. In another preferred embodiment, the groove 12 also can merely formed at the lower side of the edge emitting laser diode 20 and extends to the opposite surface of the heat-dissipating substrate 10. Alternatively, the groove 12 is formed by assembling two substrates with a proper distance therebetween. The present invention places no limitation thereon.

In a preferred embodiment, the metal solder layer 30 is made of a material containing gold-tin alloy, and is located at two sides of the groove 12, so as to fixedly attach the edge emitting laser diode 20 to the heat-dissipating substrate 10. In other preferred embodiments, the metal solder layer 30 also can be made of, for example, pure tin, gold-tin alloy or other metal materials or alloy materials containing other metal materials, and the present invention places no limitation thereon.

By lowering the active area 22, the edge emitting laser diode 20 has the active area 22 very close to the flat surface 11 of the heat-dissipating substrate 10. In a preferred embodiment, the distance from the active area 22 to the contacting surface between the edge emitting laser diode 20 and the metal solder layer 30 can be 2 μm to 14 μm, so that the heat generated by the active area 22 is directly conducted to the flat surface 11 of the heat-dissipating substrate 10 through the metal solder layer 30, thereby reaching an effect for shortening the heat conducting path.

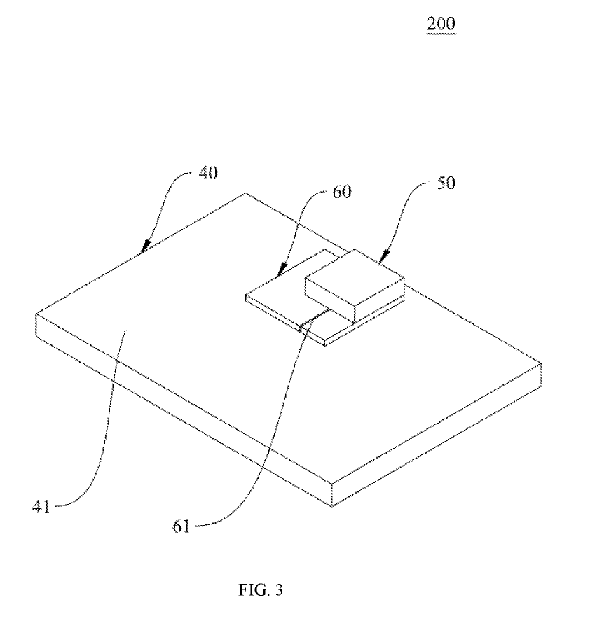

The disclosed heat-dissipating semiconductor assembly can be embodied in more ways different from that described in the foregoing embodiment. The second embodiment of the present invention is illustrated as below, and please refers to FIG. 3, which is a perspective schematic view of the second embodiment of the present invention.

The present embodiment is different from the first embodiment on the heat-dissipating structure, and all the similarities will not be discussed any further hereinafter.

The present embodiment provides a heat-dissipating semiconductor assembly. The heat-dissipating semiconductor assembly 200 primarily comprises a heat-dissipating substrate 40, an edge emitting laser diode 50, and a metal solder layer 60. The heat-dissipating substrate 40 has its one side formed with a flat surface 41. The metal solder layer 60 is deposited on the flat surface 41 of the heat-dissipating substrate 40, and the metal solder layer 60 has a groove 61.

The heat-dissipating substrate 40 can be a ceramic board that features high thermal conductivity, low thermal resistance, long service life, and good thermal endurance. With high thermal conductivity and good thermal endurance, the ceramic board can effectively conduct heat for heat dissipation.

Particularly, the heat-dissipating substrate 40 preferably can be made of a ceramic material containing aluminum nitride (AlN), silicon carbide (SiC), or aluminum oxide (Al₂O₃) or a composite material composed of the foregoing materials, and the present invention places no limitation thereon. In one preferred embodiment, the heat-dissipating substrate is preferably made of a material based on aluminum nitride (AlN). With high thermal conductivity and low coefficient of thermal expansion, aluminum nitride is effective in preventing offset beam of the edge emitting laser diode 50 that would otherwise be caused by thermal expansion or contract of the heat-dissipating substrate 40 made of other materials under thermal variation.

In a preferred embodiment, the metal solder layer 60 is made of a material containing gold-tin alloy. The metal solder layer 60 is provided with a groove 61 for giving place to the ridge 51 of the edge emitting laser diode 50. The metal solder layer 60 can also made of, for example, pure tin (Sn), gold-tin alloy or other metal materials or alloy materials containing other metal materials, and the present invention places no limitation thereon.

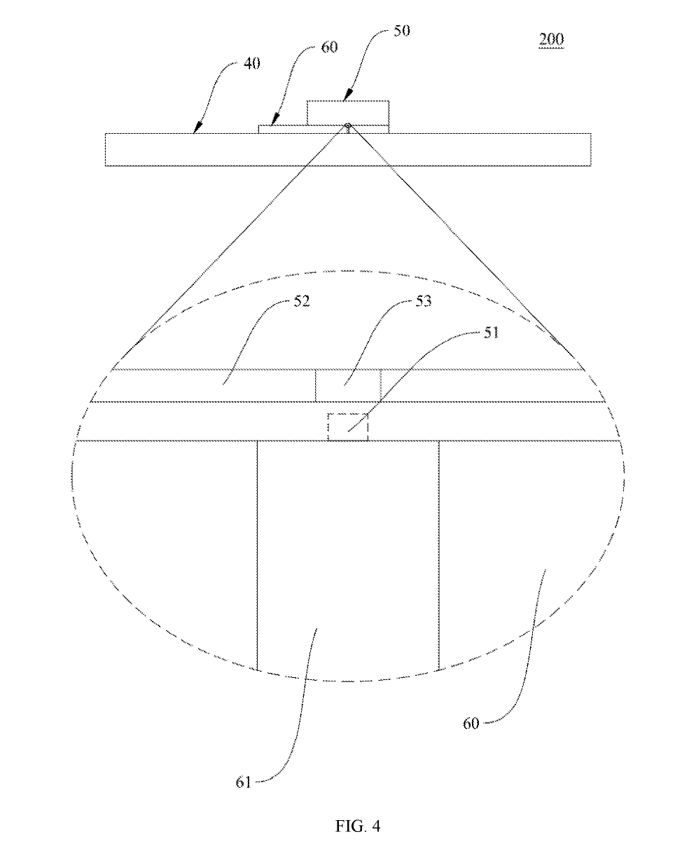

Please refer to FIG. 4 for a cross-sectional view of the second embodiment of the present invention.

The edge emitting laser diode 50 comprises an active area 52 and a ridge 51 deposited on one side of a light-emitting area 53 of the active area 52. Particularly, the ridge 51 can be a P-type semiconductor, and the active area 52 can be an area between P and N, which depends on the type of the edge emitting laser diode 50 used. An electrode layer (not shown in drawing) is optionally formed on the bottom side of the ridge 51 to cover the outside of the ridge 51. The electrode layer can extend in both sides to the upper side of the metal solder layer 60. The edge emitting laser diode 50 is mounted on the metal solder layer 60. By lowering the active area 52 of the edge emitting laser diode 50, the active area 52 of the edge emitting laser diode 50 is drawn closer to one side of the heat-dissipating substrate 40. The edge emitting laser diode 50 has its optical output direction parallel to the flat surface 41 of the heat-dissipating substrate 40. The metal solder layer 60 is also provided with a groove 61. The ridge 51 of the edge emitting laser diode 50 is aligned with an opening of the groove 61 on the metal solder layer 60, thereby preventing the metal solder layer 60 from contacting the ridge 51 of the edge emitting laser diode 50. While the ridge 51 in the drawing is depicted as a block, the ridge 51 can be one jutting out of, recessed from, or flush with the bottom side of the laser semiconductor, according to the type of the laser semiconductor. The present invention places no limitation on the way the ridge 51 is realized. Particularly, the edge emitting laser diode 50 can be a ridge-type laser diode, a planar buried laser diode, a stripe buried laser diode, or other laser diodes having a ridge structure. The present invention places no limitation thereon.

The groove 61 on the metal solder layer 60 is wider than the ridge 51 of the edge emitting laser diode 50. Particularly, the minimum width of the groove 61 of the metal solder layer 60 is about 1˜2 μm greater than the width of the ridge 51 of the edge emitting laser diode 50, wherein a proper margin has to be maintained lest the ridge 51 should be damaged.

By lowering the active area 52, the edge emitting laser diode 50 has the active area 52 very close to the metal solder layer 60. In a preferred embodiment, the distance from the active area 52 to the contacting surface between the edge emitting laser diode 50 and the metal solder layer 60 can be 2 μm to 14 μm, so that the heat generated by the active area 52 is directly conducted to the flat surface 41 of the heat-dissipating substrate 40 through the metal solder layer 60, thereby reaching an effect for shortening the heat conducting path.

As mentioned above, the disclosed heat-dissipating semiconductor assembly has the edge emitting laser diode deposited on the metal solder layer and has the active area of the edge emitting laser diode close to the heat-dissipating substrate by lowering the active area of the edge emitting laser diode, thereby shortening the heat conducting path of the edge emitting laser diode, and effectively conducting the heat generated by the edge emitting laser diode to the heat-dissipating substrate in the shortened heat conducting path. Moreover, the disclosed heat-dissipating semiconductor assembly has the groove formed on the heat-dissipating substrate, and has the ridge of the edge emitting laser diode aligned with the opening of the groove, thereby preventing the heat-dissipating substrate from damaging the ridge of the edge emitting laser diode and in turn ruining its light-emitting quality.

The present invention is more detailed illustrated by the above preferable example embodiments. While example embodiments have been disclosed herein, it should be understood that other variations may be possible. Such variations are not to be regarded as a departure from the spirit and scope of example embodiments of the present application, and all such modifications as would be obvious to one skilled in the art are intended to be included within the scope of the following claims.

What is claimed is:

1. A heat-dissipating semiconductor assembly, comprising:
a heat-dissipating substrate, having one side formed with a flat surface; and
an edge emitting laser diode, including an active area and a ridge deposited on one side of a light-emitting area of the active area, wherein the edge emitting laser diode is mounted on the heat-dissipating substrate, and by lowering the active area of the edge emitting laser diode, the active area of the edge emitting laser diode is drawn closer to one side of the heat-dissipating substrate, in which the edge emitting laser diode has an optical output direction parallel to the flat surface of the heat-dissipating substrate, and the heat-dissipating substrate has a groove so that the ridge of the edge emitting laser diode is aligned with an opening of the groove of the heat-dissipating substrate, thereby preventing the heat-dissipating substrate from contacting the ridge of the edge emitting laser diode.

2. The heat-dissipating semiconductor assembly of claim 1, further comprising a metal solder layer deposited on the heat-dissipating substrate and located at two sides of the groove for holding the edge emitting laser diode in position.

3. The heat-dissipating semiconductor assembly of claim 2, wherein the distance from the active area to the contacting surface between the edge emitting laser diode and the metal solder layer is 2 μm to 14 μm.

4. The heat-dissipating semiconductor assembly of claim 3, wherein the metal solder layer is made of a material containing gold-tin alloy.

5. The heat-dissipating semiconductor assembly of claim 3, wherein the heat-dissipating substrate is a ceramic board.

6. The heat-dissipating semiconductor assembly of claim 5, wherein the heat-dissipating substrate is made of a material containing aluminum nitride (AlN), silicon carbide (SiC), or aluminum oxide (Al₂O₃).

7. The heat-dissipating semiconductor assembly of claim 3, wherein the width of the groove is wider than the width of the ridge of the edge emitting laser diode.

8. The heat-dissipating semiconductor assembly of claim 2, wherein the groove extends across the flat surface of the heat-dissipating substrate from one side to the opposite side.

9. A heat-dissipating semiconductor assembly, comprising:
a heat-dissipating substrate, having one side formed with a flat surface;
a metal solder layer, being deposited on the flat surface of the heat-dissipating substrate and having a groove; and
an edge emitting laser diode, including an active area and a ridge deposited on one side of a light-emitting area of the active area, wherein the edge emitting laser diode is mounted on the metal solder layer, and by lowering the active area of the edge emitting laser diode, the active area of the edge emitting laser diode is drawn close to one side of the heat-dissipating substrate, in which the edge emitting laser diode has an optical output direction parallel to the flat surface of the heat-dissipating substrate, and the ridge of the edge emitting laser diode is aligned with an opening formed in the groove of the metal solder layer, thereby preventing the metal solder layer from contacting the ridge of the edge emitting laser diode.

10. The heat-dissipating semiconductor assembly of claim 9, wherein the distance from the active area to the contacting surface between the edge emitting laser diode and the metal solder layer is 2 μm to 14 μm.

11. The heat-dissipating semiconductor assembly of claim 10, wherein the metal solder layer is made of a material containing gold-tin alloy.

12. The heat-dissipating semiconductor assembly of claim 10, wherein the heat-dissipating substrate is a ceramic board.

13. The heat-dissipating semiconductor assembly of claim 12, wherein the heat-dissipating substrate is made of a material containing aluminum nitride (AlN), silicon carbide (SiC), or aluminum oxide (Al₂O₃).

14. The heat-dissipating semiconductor assembly of claim 10, wherein the width of the groove is wider than the width of the ridge of the edge emitting laser diode.
